(19) United States
(12) Patent Application Publication
(10) Pub. No.: US 2002/0146920 A1
(43) Pub. Date: Oct. 10, 2002

(54) Method of soldering contact pins and the contact pins

(76) Inventor: Shinichi Sugiyama, Tokyo (JP)

Correspondence Address: FLYNN, THIEL, BOUTELL & TANIS, P. C., 2026 Rambling Road, Kalamazoo, MI, 49008-1699, US

(21) Appl. No.: 10/105,957

(22) Filed: Mar. 21, 2002

(30) Foreign Application Priority Data
Mar. 23, 2001 (JP) 2001-86191

(51) Int. Cl. H05K 1/00

(52) U.S. Cl. 439/66

(57) ABSTRACT

A method of soldering contact pins and the contact pins for realizing a probe card, wherein the contact pins can be arranged on a surface of the probe card with narrow pitches and is excellent in maintainability, can sufficiently absorb variations in height of testing electrodes of a semiconductor chip, thereby ensuring stable contact between all the contact pins and the testing electrodes of the semiconductor chip, and capable of transmitting signals at high speed. The method of soldering contact pins for standing contact pins upright on a surface of a wiring board of a probe card, said contact pins being brought into contact with and connected to testing electrodes of a semiconductor chip for testing electric characteristics of the semiconductor chip, said method comprising arranging pedestals for soldering of the contact pins and solder balls on electrode pads of the wiring board in proximity to one another, melting the solder balls to form fillets between the electrode pads and the pedestals for soldering, thereby fixing the pedestals 10c for soldering to the electrode pads.

### FIELD OF THE INVENTION

The invention relates to contact pins connected to testing electrodes of a semiconductor chip for testing electric characteristics of the semiconductor chip and a method of soldering the contact pins.

### BACKGROUND OF THE INVENTION

Electronic devices on which semiconductor integrated circuits are mounted (hereinafter referred to as devices) have made recently significant progress toward the miniaturization and low cost thereof, and the demand for the miniaturization and the low cost of the devices has strongly intensified. Further, as the strong demand for the miniaturization of the devices is further intensified, a manner of supply of devices is changed. The devices are generally supplied in the manner that the semiconductor chips which are formed by cutting a wafer are connected to a lead frame by wire bonding, and the semiconductor chips are sealed by plastics or ceramics.

However, if a technique for directly mounting devices on a printed circuit board in a state of a semiconductor chip per se, namely, in a state where the devices are cut from a semiconductor wafer (hereinafter referred to as a bare chip) is developed, the supply of the devices in a bare chip state at a low cost has been demanded. When the devices are supplied in a bare chip state, all the tests are needed to be carried out for the devices in a semiconductor wafer state so as to guarantee the quality thereof. That is, the semiconductor chips in a semiconductor wafer state have to be subjected to a burn-in test and the maximum speed operation test.

In a normal device testing process, the devices are subjected to a direct current (DC) test and a low speed function test by combining a semiconductor testing device (hereinafter referred to as an IC tester) and a wafer prober in a wafer test serving as a pre-treatment test, so that defective semiconductor chips are screened through such tests. After the devices are packaged by plastics or ceramics to be formed in final devices, they are subjected to a burn-in test as a post-treatment test by a semiconductor burn-in testing device (hereinafter referred to as a TBT), so that initial defective semiconductor chips are screened through the burn-in test. Thereafter, the devices are subjected to a high speed function test (sorting test) by the IC tester, thereby sorting the non-defective semiconductor chips in performance.

In order to supply the devices in a bare chip state, all the burn-in test and the sorting test which have been effected as a post-treatment test have to be transferred to a test in the semiconductor wafer state (normal pre-treatment test). A wafer leveling burn-in device (hereinafter referred to as a WLTBT) has been already developed as a device for subjecting the devices in the semiconductor wafer state to the burn-in test, wherein the WLTBT employs a continuous surface type system, namely, a probe card (hereinafter referred to a probe card for WLTBT) for connecting test signals from the WLTBT to testing electrodes of the semiconductor chip on the semiconductor wafer can contact all the testing electrodes of the semiconductor chips on the wafer at a time.

Further, various systems or types of a probe card for connecting test signals of the IC tester to testing electrodes of the semiconductor chips on the semiconductor wafer (hereinafter referred to as a probe card for IC tester) have been hitherto developed. Conventional systems of the probe card are roughly classified in the following three types, namely, a cantilever type, a vertical needle type and a membrane type. The cantilever type has been commonly frequently used and made of contact pins formed by bending long needle-like metal (such as tungsten) at a blunt angle at the portion close to contact terminal side of the testing electrodes, and the contact pins are connected and fixed to a printed wiring board for a probe card while it is inclined aslant. With cantilever type, the contact pins can be arranged with narrow pitches but they are very difficultly placed in a wider range of surface. Further, the contact pins have a long terminal length, causing a problem of inferior electronic characteristic and low speed.

On the other hand, the vertical needle type is a system for making upright needle-like contact pins vertically wherein the contact pins at the terminal tip end side are held by each hole made of ceramic material or the like so that the contact pins can be disposed in a wider range of surface and speeded up with ease, but they are hardly arranged with narrow pitches because of the limitation of fine processing of ceramics. The membrane type is a system for forming bumps on an insulating film and elastic material sheet is disposed on the back of the insulating film for receiving a contact pressure which is received by each bump. In the membrane type, electric signals to be applied to each bump are connected to each pad of a wiring board which is disposed at the innermost back face inside the elastic material sheet via a conductive material. With the membrane type, the contact pins can be disposed in a wider range of surface and arranged with narrow pitches with high speed, but the membrane type had a drawback of hardly following variations in height of each testing electrode.

Still further, since such conventional contact pins are fixed to the wiring board by welding or the like, they can not be removed from the wiring board when any inconvenience occurs thereto, and the probe card has to be replaced with another as a whole, causing a problem of the maintainability and cost efficiency.

As mentioned in detail above, the conventional probe card has merits and demerits, and hence it can not satisfy the surface disposition with narrow pitches, high speed transmission of signals and the follow-up property relative to variations in height of each testing electrode. However, since the present semiconductor chips are developed rapidly in the miniaturization, speed and multi-pins, there is a strong demand for a probe card having all the advantages described above.

### SUMMARY OF THE INVENTION

The invention has been developed to solve the problems of the conventional probe card, and it is an object of the invention to provide a method of soldering contact pins which can be disposed with narrow pitches on the surface, excellent in maintainability, capable of sufficiently absorbing the variation in height of the testing electrodes, thereby ensuring stable contact between all the contact pins and testing electrodes, and realizing a probe card capable of transmitting signals at high speed, and another object is to provide contact pins.

To achieve the above object, the invention employs first means as a method of soldering contact pins for standing contact pins 10 upright on a surface of a wiring board 20 of a probe card, said contact pins 10 being brought into contact with and connected to testing electrodes of a semiconductor chips for testing electric characteristics of the semiconductor chip, wherein the method comprises the steps of arranging pedestals 10c for soldering of the contact pins 10 and solder balls 30 on electrode pads 21 of the wiring board 20 in proximity to one another, melting the solder balls 30 to form fillets 31 between the electrode pads 21 and the pedestals 10c for soldering, thereby fixing the pedestals 10c for soldering to the electrode pads 21.

The invention employs second means wherein the solder balls 30 in the first means are irradiated with laser light so that the solder balls 30 are molten.

The invention employs third means wherein the first or second means further comprises the steps of bringing the pedestals 10c for soldering onto which flux 32a is stuck in advance into contact with the electrode pads 21 so as to transfer the flux 32a onto the electrode pads 21 to form a transfer flux 32b, arranging the solder balls 31 onto the transfer flux 32b, thereby placing the pedestals 10c for soldering on the transfer flux 32b.

The invention employs fourth means comprising plural contact pins 10 arranged on a surface of a wiring board 20 of a probe card, wherein the contact pins 10 are brought into contact with and connected to testing electrodes of a semiconductor chip for testing electric characteristics of the semiconductor chip and have grooves 10d at the surface contacting the wiring board 20.

The invention employs fifth means wherein the contact pins 10 in the fourth means has microspring sections 10b between tip ends 10a for contacting electrodes to be connected to the testing electrodes of the semiconductor chip and pedestals 10c for soldering which are fixed to electrode pads 21 of the wiring board 20.

### BRIEF DESCRIPTION OF THE DRAWINGS

FIG. 1(A) is a front view showing the shape of a contact pin according to a preferred embodiment of the invention, and FIG. 1(B) is a side view thereof.

FIG. 2(A) is a perspective view showing a probe card on which the contact pins according to the a preferred embodiment stand upright, and FIG. 2(B) is a plan view showing dimensions of electrode pads and pedestals for soldering.

FIG. 3(A) is a perspective view showing a step for sticking flux onto the contact pin according to the preferred embodiment, and FIG. 3(B) is an enlarged view of the main portion in FIG. 3(A), namely, the pedestal for soldering.

FIG. 4(A) is a schematic view showing a suction mechanism for moving solder balls, and FIG. 4(B) is an enlarged view of the main portion in FIG. 4(A), namely, a tip end of the suction mechanism.

FIG. 5(A) to FIG. 5(H) are side views showing a method of soldering the contact pin according to the preferred embodiment of the invention, wherein FIG. 5(A) is a view showing a wiring board and an electrode pad, FIG. 5(B) shows a state where the pedestal for soldering is brought into contact with the electrode pad, FIG. 5(C) and FIG. 5(D) are views showing a state where flux is stuck onto the electrode pad, FIG. 5(E) is a view showing a state where the solder ball is disposed on a transfer flux, FIG. 5(F) is a view showing a state where the pedestal for soldering is disposed in proximity to the solder ball, FIG. 5(G) is a view showing a state where the solder ball is heated by laser light, and FIG. 5(H) is a view showing a state where the pedestal for soldering is fixed to the electrode pad while a solder fillet is formed therebetween.

### PREFERRED EMBODIMENT OF THE INVENTION

A preferred embodiment of contact pins according to the invention is now described with reference to the attached drawings.

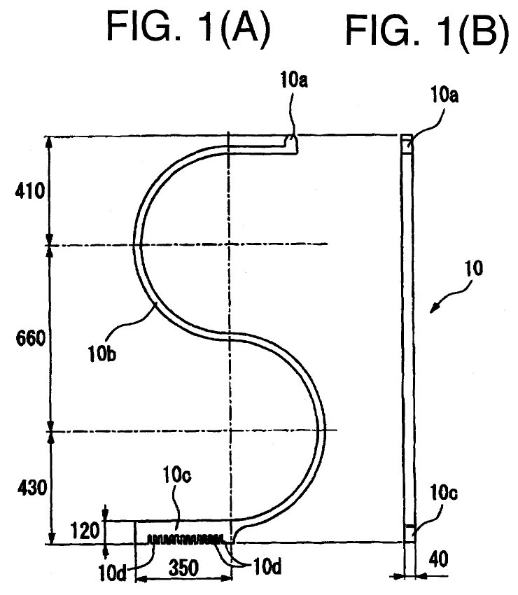

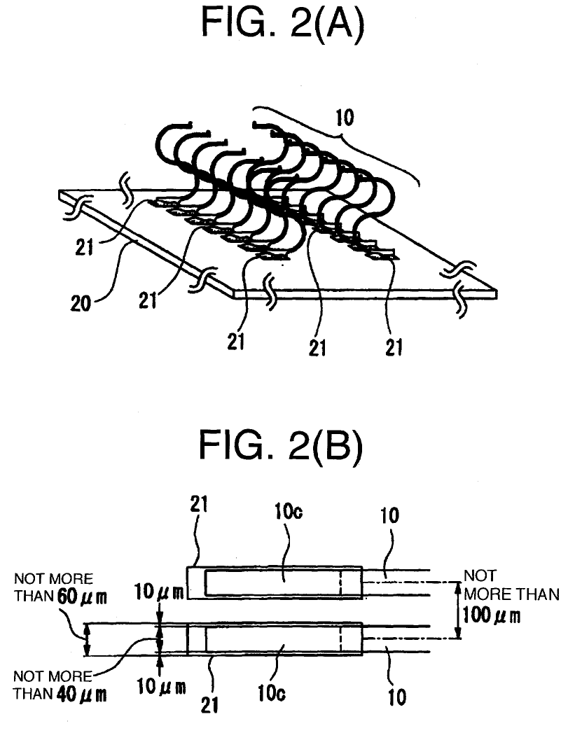

FIG. 1 and FIG. 2 are views showing the construction of the preferred embodiment. A probe card is formed by standing contact pins 10 upright on the surface of a wiring board 20 as shown in FIG. 2(A). All the units of numeric values shown in FIG. 1 are represented by micrometer (μm).

Each contact pin 10 comprises, as shown in FIG. 1(A) and FIG. 1(B), a tip end 10a for contacting an electrode which is brought into contact with and connected to a testing electrode formed on a semiconductor chip, a pedestal 10c for soldering which is fixed to an electrode pad 21 of the wiring board 20, and a microspring section 10b between the tip end 10a for contacting an electrode and the pedestal 10c for soldering. The pedestal 10c for soldering has grooves 10d formed on the contact surface between the pedestal 10c for soldering and the wiring board 20 (electrode pad 21) for strengthening solder joint between the contact pin 10 and the wiring board 20. Each of the grooves 10d has dimensions which are set at 10 μm in width and at 30 μm in depth and the grooves 10d are provided on a substantially central portion of the pedestal 10c for soldering except both end sides thereof at a given interval for ensuring the strength of the contact pin 10 (pedestal 10c for soldering).

The contact pin 10 having such a shape is made of conductive metal which is formed by a metal deposition process (additive process) utilizing, e.g. by light or X rays lithography technique with high dimensional accuracy. The conductive metal is, e.g. pure nickel or nickel based material such as nickel alloy or the like. The entire surface of the contact pin 10 is given gold plating for lowering a contact resistance.

The wiring board 20 has the electrode pads 21 on its surface for soldering the pedestals 10c for soldering thereto and has an electric signal interface function relative to a WLTBT or an IC tester. The contact pins 10 are soldered onto the electrode pads 21 by irradiating and heating with laser light utilizing solder balls 30. According to the preferred embodiment, a ceramic multi-layer board having superfine pitches is employed for the wiring board 20 which is very small in deformation caused by heat shrinkage and the like for assuring positional accuracy of the contact pins 10.

Each interval for arranging the contact pins 10 is set, e.g. at not more than 10 μm as shown in FIG. 2(B). On the other hand, each width of the electrode pad 21 in the arranging direction of each contact pin 10 is set, e.g. at not more than 60 μm while the width of each pedestal 10c for soldering in the same arranging direction is set, e.g. at not more than 40 μm.

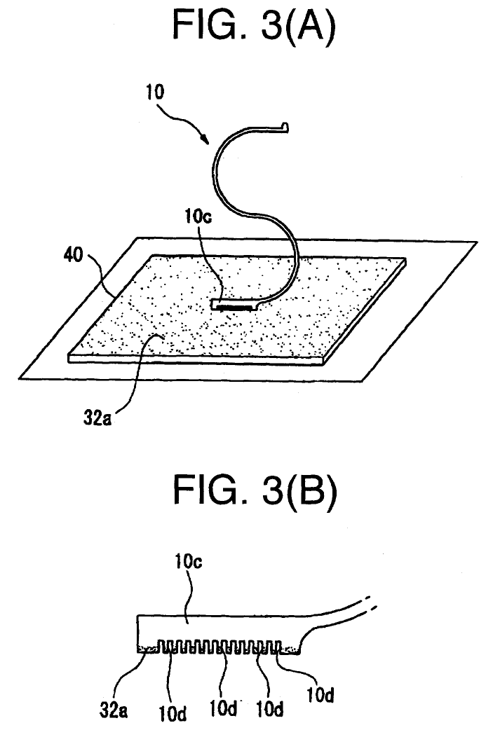

The method of soldering contact pins according to the preferred embodiment of the invention is now described with reference to FIG. 3 to FIG. 5. First of all, as shown in FIG. 3(A), the pedestal 10c for soldering is brought into contact with the surface of a plate 40 on which a flux 32a is coated in the thickness of 20 to 30 μm. As a result, the flux 32a is stuck to the pedestal 10c for soldering as shown in FIG. 3(B).

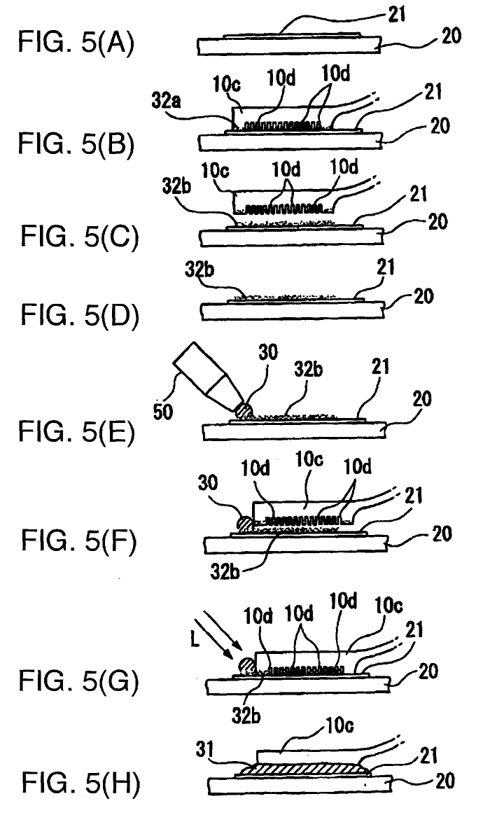

FIG. 5(A) is a side view showing a state where the electrode pad 21 is formed on the surface of the wiring board 20. The pedestal 10c for soldering to which the flux 32a is stuck as set forth above is once brought into contact with the electrode pad 21 as shown in FIG. 5(B), then the former is removed from the latter as shown in FIG. 5(C), thereby transferring the flux 32a onto the electrode pad 21 so that a transfer flux 32b is formed on the electrode pad 21 (FIG. 5(D)). With such a process, at the same time when the transfer flux 32b is formed on the electrode pad 21, the flux 32a can be stuck in advance to the pedestal 10c for soldering and the interior of the grooves 10d.

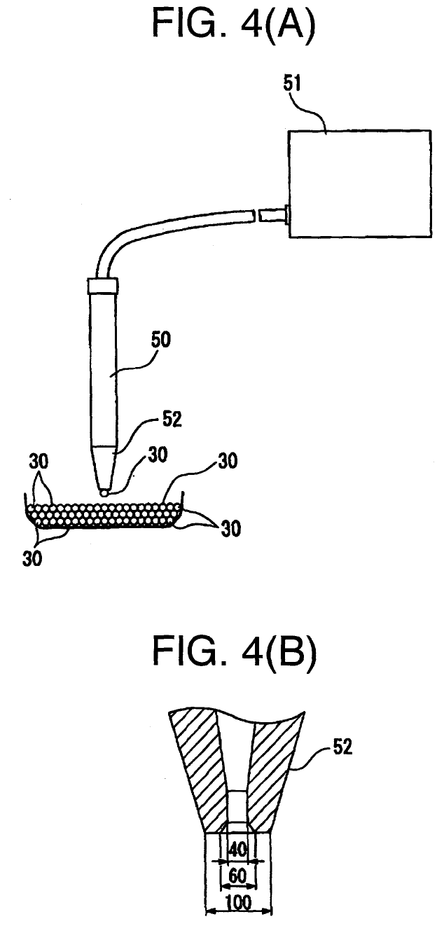

Subsequently, as shown in FIG. 5(E), the solder ball 30 is disposed on the transfer flux 32b, e.g. by a suction mechanism 50. The solder ball 30 is hardly displaced in position because it is stuck to the transfer flux 32b. The suction mechanism 50 is connected to a vacuum pump 51 as shown in FIG. 4(A), and sucks the solder ball 30 at its tip end 52 so as to move the solder ball 30. The dimensions of the tip end 52 of the suction mechanism 50 are set to an extent capable of sucking the solder balls 30 each having a diameter of about 100 μm one by one as shown in FIG. 4(B). All the units of numeric values shown in FIG. 4(B) are represented by micrometer (μm).

Further, the pedestal 10c for soldering is disposed on the transfer flux 32b to avoid the solder ball 30 disposed on the transfer flux 32b as shown in FIG. 5(F). As a result, both the solder ball 30 and the pedestal 10c for soldering are disposed on the electrode pad 21 in a state where they are close to each other.

In this state, as shown in FIG. 5(G), laser light L having a beam spot of about 100 μm in diameter is irradiated onto both the solder ball 30 and the pedestal 10c for soldering so as to heat them. As a result, the solder ball 30 is molten to form a solder fillet 31, which is to be stuck to the electrode pad 21 and the pedestal 10c for soldering by the transfer flux 32b on the electrode pad 21 and the flux 32a stuck to the pedestal 10c for soldering, so that the pedestal 10c for soldering is soldered to and jointed with the electrode pad 21 as shown in FIG. 5(H).

With the contact pins 10 of the invention, there is provided a construction for fixing the contact pins 10 to the electrode pad 21 by soldering, so that the contact pins 10 can be easily replaced with other contact pins, and hence they are excellent in maintainability. Particularly, a solder having a quantity suited for soldering and jointing the contact pins 10 by use of the solder ball 30 can be easily supplied so that a short circuit between adjacent contact pins 10 can be prevented. Further, using the laser light L, the solder ball 30 can be concentratedly heated so that the contact pins 10 is rendered with small pitches with high heat efficiency and the heat deformation of the wiring board 20 can be reduced. Still further, since the flux 32a is stuck to the pedestal 10c for soldering in advance and it is transferred to the electrode pad 21, so that the flux 32a having a proper quantity can be supplied to the electrode pad 21 with ease, and also the same flux can be stuck to the pedestal 10c for soldering, thereby realizing reduction of labor and shorter working hour involved in the operation.

Yet, the grooves 10d are formed in the pedestal 10c for soldering, a sticking property of the flux 32a is excellent while the molten solder ball 30 enters the interiors of the grooves 10d so that the solder joint between each contact pin 10 and each electrode pad 21 becomes firm, thereby surely fixing each contact pin 10 to each electrode pad 21. Further, since each contact pin 10 has the microspring section 10b having a microspring structure, when the semiconductor chips are tested while the wiring boards 20 are disposed to oppose each other on the semiconductor chips at given height, the contact pins 10 can absorb the variations in height of the testing electrodes, thereby allowing the tip ends 10a for contacting electrodes to surely contact the testing electrodes.

Although the shapes of the respective components and the combination thereof according to the preferred embodiment of the invention are merely exemplified, they can be variously changed based on the designing demand in a scope of the invention without departing from a gist of the invention. In the illustrated embodiment, although the microspring section 10b having a microspring structure is formed of an S-shape, it may be formed of a folding type in which U-shape continuously alternates in opposite direction, and may be formed of a zigzag type wherein the microspring section 10b having a reduced width can obtain elastic property which is equivalent to the S-shape type by increasing the folding sections as many as possible, so that contact pins 10 can be disposed on the wiring board 20 with high density.

As mentioned in detail above, according to the method of soldering contact pins and the contact pins, it is possible to realize the contact pins which can be surely fixed to the wiring board with narrow pitches, and to remove the contact pins from the wiring board with ease, thereby rendering the contact pins excellent in maintainability and cost efficiency. Further, the contact pins can be surely brought into contact with multiple testing electrodes which are arranged on the semiconductor chip with narrow pitches while sufficiently absorbing variations in height of the testing electrodes, and further, each contact pin per se is very small and the entire length thereof is very short so that the signals can be transmitted at high speed.

What is claimed is:

1. A method of soldering contact pins for standing contact pins upright on a surface of a wiring board of a probe card, said contact pins being brought into contact with and connected to testing electrodes of a semiconductor chips for testing electric characteristics of the semiconductor chip, said method comprising:
arranging pedestals for soldering of the contact pins and solder balls on electrode pads of the wiring board in proximity to one another;
melting the solder balls to form fillets between the electrode pads and the pedestals for soldering, thereby fixing the pedestals for soldering to the electrode pads.

2. The method according to claim 1, wherein the solder balls are irradiated with laser light so that the solder balls are molten.

3. The method according to claim 1 or 2, further comprising bringing the pedestals for soldering onto which flux is stuck in advance into contact with the electrode pads so as to transfer the flux onto the electrode pads to form a transfer flux, arranging the solder balls onto the transfer flux, thereby placing the pedestals for soldering on the transfer flux.

4. Plural contact pins arranged on a surface of a wiring board of a probe card, said contact pins being brought into contact with and connected to testing electrodes of a semiconductor chip for testing electric characteristics of the semiconductor chip and having grooves 10d at the surface contacting the wiring board.

5. The contact pins according to claim 4, wherein the contact pins have microspring sections between tip ends for contacting electrodes to be connected to the testing electrodes of the semiconductor chip and pedestals for soldering which are fixed to electrode pads of the wiring board.
